(19) United States
(12) Patent Application Publication
(10) Pub. No.: US 2025/0209033 A1
(43) Pub. Date: Jun. 26, 2025

(54) COMMUNICATION VIA SERIALIZER/DESERIALIZER

(71) Applicant: STMicroelectronics International N.V., Geneva (CH)

(72) Inventors: Andrew COFLER, VOIRON (FR); David JACQUET, VAULNAVEYS LE HAUT (FR); Massimo POZZONI, PAVIA (IT)

(21) Appl. No.: 18/969,582

(22) Filed: Dec. 5, 2024

(30) Foreign Application Priority Data
Dec. 20, 2023 (FR) FR2314545

(51) Int. Cl. G06F 13/42

(52) U.S. Cl. CPC G06F 13/4282; G06F 2213/0002

(57) ABSTRACT

An electronic device adapted to implementing a communication by means of a serializer/deserializer is provided. An example electronic device includes a first memory adapted to storing first software adapted to initializing the communication, the first software being different from second software adapted to implement the communication.

### CROSS REFERENCE TO RELATED APPLICATION(S)

This application claims the priority benefit of French patent application number FR2314545, filed on Dec. 20, 2023, entitled “Communication par sérialiseur/désérialiseur”, which is hereby incorporated by reference to the maximum extent allowable by law.

### TECHNICAL FIELD

The present disclosure generally concerns electronic circuits and devices, and communications between a plurality of electronic circuits or devices. The present description more particularly relates to communications using a serializer/deserializer module.

### BACKGROUND

Serializer/deserializer (SerDes) components, or serializer/deserializer modules, are components enabling electronic devices to implement communications transferring a high data rate. These serializer/deserializer components are generally integrated to the electronic devices implementing the communication.

It would be desirable to be able to improve, at least partly, certain aspects of communications using serializer/deserializer components.

### BRIEF SUMMARY

There exists a need for more efficient communications by means of a serializer/deserializer.

There exists a need for electronic devices implementing communications using more efficient serializer/deserializer components.

There exists a need for electronic devices implementing communications using more compact components.

An embodiment overcomes all or part of the disadvantages of electronic devices implementing communications using serializer/deserializer components.

An embodiment overcomes all or part of the disadvantages of known methods for initializing a communication by means of a serializer/deserializer.

An embodiment overcomes all or part of the disadvantages of known methods of communication by means of a serializer/deserializer.

An embodiment provides an electronic device only storing software adapted to initializing a communication by means of a serializer/deserializer.

An embodiment provides a method for initializing a communication by means of a serializer/deserializer implemented by the previously-described device.

An embodiment provides an electronic device adapted to implementing a communication by means of a serializer/deserializer comprising a first memory adapted to storing first software adapted to initializing the communication, the first software being different from second software adapted to implementing the communication.

Another embodiment provides a method of initialization of a communication by means of a serializer/deserializer by an electronic device comprising a first memory adapted to storing first software adapted to initializing the communication, the first software being different from second software adapted to implementing the communication.

According to an embodiment, the first memory is a programmable read-only memory.

According to an embodiment, the first software is an abbreviated version of the second software.

According to an embodiment, once the first software has been used, the device is adapted to receiving the second software.

According to an embodiment, the second software is sent by a first control circuit external to the device.

According to an embodiment, the second software is stored in a second memory of the device.

According to an embodiment, the second memory is a static random-access memory of a serializer/deserializer module of the device.

According to an embodiment, the first software is adapted to initializing the communication having a first data rate lower than a second data rate of the communication when it is implemented by the second software.

According to an embodiment, the first software is adapted to initializing the communication having first functionalities different from second functionalities of the communication when it is implemented by the second software.

Another embodiment provides a method of communication by means of a serializer/deserializer comprising the above-described method.

Another embodiment provides an electronic system comprising at least one device described hereabove.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows an electronic system within which is implemented, according to an embodiment, a communication by means of a serializer/deserializer; and

FIG. 2 shows an implementation mode of a method of starting a communication by means of a serializer/deserializer within the system of FIG. 1.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

The embodiments described hereafter concern devices adapted to implementing a communication by means of a serializer/deserializer. Such a communication is a communication between electronic devices using serializer/deserializer (SerDes) components, integrated to the electronic devices, to transmit data. Such components enable to transmit data, normally broadcast over a plurality of communication channels, over a single communication channel. In other words, such a component enables to serialize data received in parallel on a plurality of inputs. To implement such a communication, electronic devices generally need to be able to implement software associated with the communication by means of a serializer/deserializer. This software is generally a very low-level program, also called microcode or firmware.

The embodiments described hereafter overcome a problem of storage of the software associated with the communication by means of a serializer/deserializer in an electronic device implementing it. Indeed, such software is generally stored in a non-volatile memory external to the serializer/deserializer component of the device. For reasons of bulk and of financial cost, certain devices cannot comprise a non-volatile memory enabling to store software. For this purpose, the embodiments described hereafter comprises a programmable read-only memory, that is, a memory which can only be programmed once, adapted to storing an abbreviated version of the software only enabling to initialize a limited communication by means of a serializer/deserializer. Once the communication has been initialized, the serializer/deserializer component of the device is adapted to receiving and to storing, in one of its internal memories, the complete software.

Further, these embodiments can be applied to any electronic system using one or a plurality of serializer/deserializer components, such as, for example, communication systems, such as antennas, for example active antennas, data storage systems, such as data centers, etc. These embodiments are particularly adapted to electronic systems comprising a large number of electronic devices adapted to implementing a communication by means of a serializer/deserializer between one another.

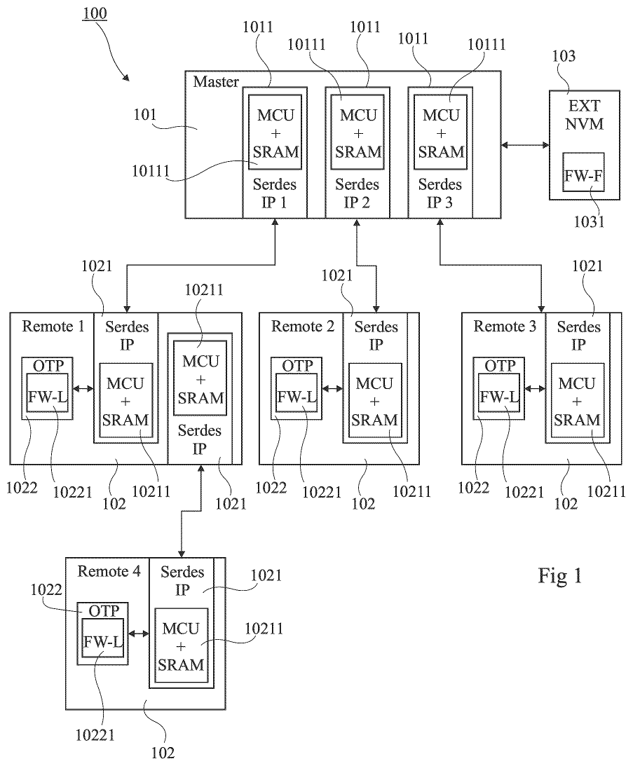

FIG. 1 shows, schematically and in the form of blocks, an embodiment of an electronic system 100 according to an embodiment.

System 100 comprises a plurality of electronic devices, for example at least two electronic devices, adapted to implementing a communication by means of a serializer/deserializer. In the example shown in FIG. 1, system 100 comprises five electronic devices, among which one master, or commander, electronic device (101) and four remote slave, or responder, electronic devices (102) (Remote 1, Remote 2, Remote 3, Remote 4).

Each electronic device 101, 102 of system 100 comprises at least one serializer/deserializer component 1011, respectively 1021, or serializer/deserializer module enabling it to implement a communication by means of a serializer/deserializer with another device of system 100. More particularly, each electronic device 101, 102 comprises a serializer/deserializer module for each other electronic device with which it is adapted to implementing a communication by means of a serializer/deserializer. In other words, if an electronic device is adapted to communicating with two other electronic devices, it then comprises two serializer/deserializer modules. In the example shown in FIG. 1, electronic device 101 is adapted to implementing a communication by means of a serializer/deserializer with three of devices 102 (Remote 1, Remote 2, Remote 3), and a device 102 (Remote 4) is adapted to implementing a communication with only one of the other devices 102 (Remote 1). Thus, device 101 comprises three serializer/deserializer modules, and each device 102 comprises one serializer/deserializer module, except for one device 102 (Remote 1), which comprises two serializer/deserializer modules.

More particularly, device 101 comprises:
a serializer/deserializer module 1011 bearing reference “Serdes IP 1” adapted to communicating with the device 102 bearing reference “Remote 1”;
a serializer/deserializer module 1011 bearing reference “Serdes IP 2” adapted to communicating with the device 102 bearing reference “Remote 2”; and
a serializer/deserializer module 1011 bearing reference “Serdes IP 3” adapted to communicating with the device 102 bearing reference “Remote 3”.

According to an embodiment, each component 1011, 1021 comprises a control circuit accompanied by a memory 10111 (MCU+SRAM), respectively 10211 (MCU+SRAM). According to an example, the control circuit is a processor, a microprocessor, a controller, or a microcontroller. According to a preferred embodiment, main control circuit 101 is a microcontroller. According to a preferred embodiment, the memory is a random access memory, as, preferably, a static random access memory (SRAM).

According to an example, the electronic device is a complex electronic device, such as a processor or a microprocessor.

According to an embodiment, each device 102 comprises, in addition to its component 1021, at least one programmable read-only memory 1022 (OTP) of small capacity. According to an example, memory 1022 has a capacity of a few kilobytes, for example smaller than 5 kBytes. According to an embodiment, programmable read-only memory 1022 is a one-time programmable (OTP) memory.

Further, system 100 also comprises at least one non-volatile memory 103 (EXT NVM) external to devices 101 and 102. According to an example, non-volatile memory 103 may be accessible to device 101, but is not accessible to devices 102. According to an example, the storage capacity of memory 103 is greater than the storage capacity of the programmable read-only memories 1022 of devices 102.

To implement a communication by means of a serializer/deserializer, each device 101, 102 has to implement software adapted to implementing such a communication. More particularly, each control circuit 10111, respectively 10211, has to implement software adapted to implementing such a communication. For this purpose, such software has to be stored in the memory coming along with each control circuit 10111, respectively 10211.

According to an embodiment, this software is a microcode adapted to directly send commands to one or more electronic circuits and components responsible for implementing communication by serializer/deserializer. As mentioned hereabove, this software is generally a very low-level program, also called microcode or firmware. A very low-level program is a computer program enabling to directly control hardware components, with no other software intermediary.

According to an embodiment, each device 102 is adapted to storing in its memory 1022, instead of the software for implementing a communication by means of a serializer/deserializer, software 10221 (FW_L) adapted to, at least, initializing a limited communication by means of a serializer/deserializer. Software 1031 (FW_F) enabling to implement a communication by means of a serializer/deserializer is stored in the external non-volatile memory 103 of system 100 to initialize a limited serializer/deserializer communication, meaning trigger activate or circuits responsible for implementing a limited serializer/deserializer communication. According to one example, the software 1031 is adapted to trigger or activate circuits responsible for implementing serializer/deserializer communication. Software 1031 is only supplied to device 102 when a communication is initialized. When software 1031 is supplied to device 102, it is stored in the memory associated with the control circuit 10211 of its module 1021.

According to an embodiment, software 10221 is different from software 1031 in that it comprises fewer functionalities. According to an embodiment, software 10221 is an abbreviated or simplified version of software 1031. Thus, the code of software 10221 is smaller than the code of software 1031. The code of software 10221 can thus be stored in memory 10211, while the code of software 1031 is too bulky to be stored by this memory. The advantage thus here is to be able to avoid the installation of a non-volatile memory external to module 1021, and thus to make system 100 more compact.

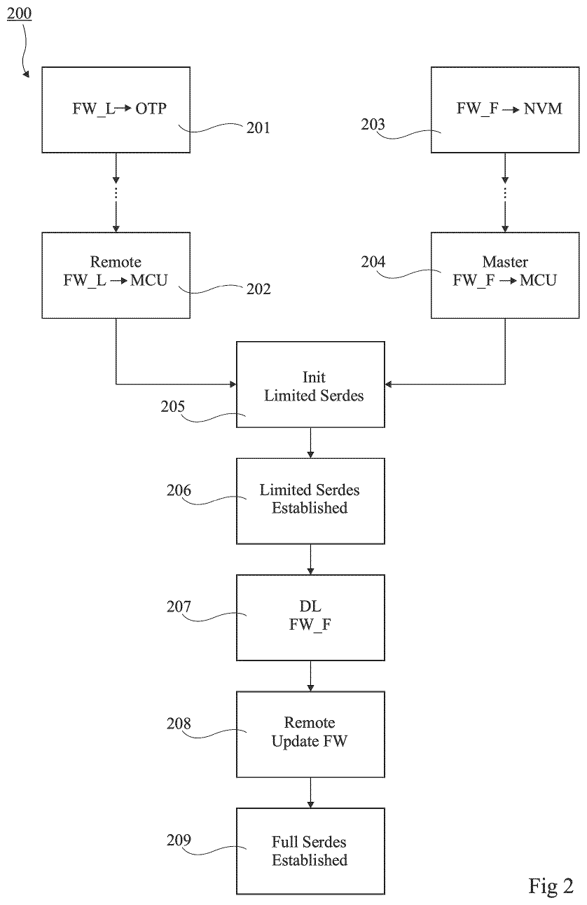

According to an embodiment, software 10221 enables to initialize a communication by means of a serializer/deserializer at a lower data rate than the data rate of such a communication implemented by software 1031. The initialization of such a communication is described in detail in relation with FIG. 2.

According to an alternative embodiment, software 10221 enables to initialize a communication by means of a serializer/deserializer at the same data rate as the data rate of such communication implemented by software 1031, having different functionalities. In particular, a communication initialized by software 10221 may have fewer functionalities than a communication initialized by software 1031. According to an example, software 10221 may not implement functionalities related to the adaptation to the environment in which system 100 is located, as for example an adaptation to ambient temperature.

According to still another alternative embodiment, software 10221 may be used to initialize a communication by means of a serializer/deserializer with a lower data rate and different functionalities than a communication implemented by software 1031.

An advantage of this embodiment is that, by making software 10221 directly accessible to devices 102, the latter can initiate a communication autonomously. Indeed, it could have been thought of installing a communication channel only dedicated to the transmission of software 1031 to device 102, but this adds communication channels to the system and therefore increases its bulk, and may also decrease its reliability.

FIG. 2 is a block diagram illustrating the initialization 200 of implementation of a method of a communication by means of a serializer/deserializer within the electronic system 100 described in relation with FIG. 1. More specifically, the communication here concerned is a communication between device 101 and one of devices 102.

At an initial step 201 (FW_L->OTP), software 10221 is stored in the programmable read-only memory 1022 of device 102. According to an example, this step is carried out after the manufacturing of device 102, for example, during a test phase. This step has the advantage of enabling a user of system 100 to store the version of software 10221 that they desire in a simple way, rather than having to ask the manufacturer of system 100 to do so.

At a step 202 (Remote FW_L->MCU), successive to step 201, device 102 wants to implement a communication by means of a serializer/deserializer with device 101. Software 10221 is downloaded from memory 1022 to module 1021, then is installed to initialize the means of a communication by serializer/deserializer.

At another initial step 203 (FW_F->NVM), software 1031 is stored in the non-volatile memory 103 of system 100. According to an example, this step may be carried out at any step in the lifetime of system 100, and more particularly at any step in the lifetime of non-volatile memory 103.

At a step 204 (Remote FW_F->MCU), successive to step 203, device 101 wants to implement a communication by means of a serializer/deserializer with device 102. Software 1031 is downloaded from memory 103 to module 1011, then is installed to initialize the communication by means of a serializer/deserializer.

At a step 205 (Init Limited Serdes), successive to steps 202 and 204, a communication by means of a serializer/deserializer is initialized. For this purpose, device 101 uses software 1031, which enables to implement a complete communication, for example at high data rate, and device 102 uses software 10221, which enables to implement a limited communication, for example at low data rate and/or having fewer functionalities. Only a limited communication can thus be initialized between devices 101 and 102, and such a communication is initialized.

In a step 206 (Limited SerDes Established), subsequent to step 205, a limited communication by means of a serializer/deserializer has been initialized and is ready for operation. According to an example, the communication can transmit and receive data at a first data rate, for example a low data rate. This first data rate is, for example, in the order of 3 Gbits/s.

At a step 207 (DL FW_F), successive to step 206, device 102 is then adapted to receiving software 1031 to fully implement the communication by means of a serializer/deserializer. For this purpose, device 101 sends, via the initialized limited communication, software 1031 to device 102.

At a step 208 (Remote Update FW), successive to step 207, software 1031 is received by device 102, which stores it in the memory 10211 of its module 1021. According to an example, software 1031 is used to update software 10221, for example, without interrupting the communication.

At a step 209 (Full SerDes Established), successive to step 208, device 102 thus uses software 1031 to implement a full communication by means of a serializer/deserializer. According to an example, the communication may transmit and receive data at a second data rate, for example a high data rate. According to an example, the second data rate is higher than the first data rate. According to an example, the second data rate is in the order of 112 Gbits/s.

According to an embodiment, initialization method 200 may be included in a communication by means of a serializer/deserializer method.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. An electronic device adapted to implementing a communication by means of a serializer/deserializer comprising a first memory adapted to storing first software adapted to initializing the communication, the first software being different from second software adapted to implementing the communication.

2. The electronic device of claim 1, wherein the first memory is a programmable read-only memory.

3. The electronic device of claim 1, wherein the first software is an abbreviated version of the second software.

4. The electronic device of claim 1, wherein, once the first software has been used, the electronic device is adapted to receiving the second software.

5. The electronic device of claim 4, wherein the second software is sent by a first control circuit external to the electronic device.

6. The electronic device of claim 4, wherein the second software is stored in a second memory of the electronic device.

7. The electronic device of claim 6, wherein the second memory is a static random-access memory of a serializer/deserializer module of the electronic device.

8. The electronic device of claim 1, wherein the first software is adapted to initializing the communication having a first data rate lower than a second data rate of the communication when it is implemented by the second software.

9. The electronic device of claim 1, wherein the first software is adapted to initializing the communication having first functionalities different from second functionalities of the communication when it is implemented by the second software.

10. An electronic system comprising at least one electronic device of claim 1.

11. The electronic device of claim 1, wherein the first software and the second software are microcodes adapted to directly send commands to one or more electronic circuits and components responsible for implementing a communication by serializer/deserializer.

12. The electronic device of claim 1, wherein initialization of the communication corresponds to triggering of one or more electronic circuits and components responsible for implementing a communication by serializer/deserializer.

13. A method of initialization of a communication by means of a serializer/deserializer by an electronic device comprising a first memory adapted to storing first software adapted to initializing the communication, the first software being different from second software adapted to implementing the communication.

14. The method of claim 13, wherein the first memory is a programmable read-only memory.

15. The method of claim 13, wherein the first software is an abbreviated version of the second software.

16. The method of claim 13, wherein, once the first software has been used, the electronic device is adapted to receiving the second software.

17. The method of claim 16, wherein the second software is sent by a first control circuit external to the electronic device.

18. The method of claim 16, wherein the second software is stored in a second memory of the electronic device.

19. The method of claim 13, wherein the first and second software are microcodes adapted to directly send commands to one or more electronic circuits and components responsible for implementing a communication by serializer/deserializer.

20. The method of claim 13, wherein initialization of the communication corresponds to triggering of one or more electronic circuits and components responsible for implementing a communication by serializer/deserializer.
